(19) United States
(12) Patent Application Publication
(10) Pub. No.: US 2003/0028834 A1
(43) Pub. Date: Feb. 6, 2003

(54) Method for sharing redundant rows between banks for improved repair efficiency

(76) Inventors: David R. Brown, Allen, TX (US); Todd A. Dauenbaugh, Richardson, TX (US); Partha Gajapathy, Richardson, TX (US)

Correspondence Address: DICKSTEIN SHAPIRO MORIN & OSHINSKY LLP, 2101 L STREET NW, WASHINGTON, DC, 20037-1526, US

(21) Appl. No.: 09/919,589

(22) Filed: Aug. 1, 2001

(51) Int. Cl. G11C 29/00

(52) U.S. Cl. 714/711

(57) ABSTRACT

A method and corresponding architecture are disclosed for sharing redundant rows between banks of a memory array. The architecture is such that sub-arrays associated with different banks are alternated and coupled via a sense amp. In addition, sub-arrays belonging to the same bank are coupled via a single row decoder. This architecture allows for adjacent sub-arrays belonging to different banks to share redundant rows, thereby effectively doubling the number of redundant rows available for use in a given bank.

### BACKGROUND OF THE INVENTION

1. Field of the Invention

The present invention relates to integrated memory circuits. More specifically, it relates to a method for sharing redundant rows between adjacent memory banks allowing for more repair flexibility.

2. Description of Prior Art

Semiconductor memories generally include a multitude of memory cells arranged in rows and columns. Each memory cell is capable of storing digital information in the form of a “1” or a “0” bit. To write (i.e., store) a bit into a memory cell, a binary memory address having portions identifying the cell's row (the “row address”) and column (the “column address”) is provided to addressing circuitry in the semiconductor memory to activate the cell, and the bit is then supplied to the cell. Similarly, to read (i.e., retrieve) a bit from a memory cell, the cell is again activated using the cell's memory address, and the bit is then output from the cell.

Semiconductor memories are typically tested after they are fabricated to determine if they contain any failing memory cells (i.e., cells to which bits cannot be dependably written or from which bits cannot be dependably read). Generally, when a semiconductor memory is found to contain failing memory cells, an attempt is made to repair the memory by replacing the failing memory cells with redundant memory cells provided in redundant rows or columns in the memory.

Conventionally, when a redundant row is used to repair a semiconductor memory containing a failing memory cell, the failing cell's row address is permanently stored (typically in pre-decoded form) on a chip on which the semiconductor memory is fabricated by programming a non-volatile element (e.g., a group of fuses, anti-fuses, or FLASH memory cells) on the chip. Then, during normal operation of the semiconductor memory, if the memory's addressing circuitry receives a memory address including a row address that corresponds to the row address stored on the chip, redundant circuitry in the memory causes a redundant memory cell in the redundant row to be accessed instead of the memory cell identified by the received memory address. Since every memory cell in the failing cell's row has the same row address, every cell in the failing cell's row, both operative and failing, is replaced by a redundant memory cell in the redundant row.

Similarly, when a redundant column is used to repair the semiconductor memory, the failing cell's column address is permanently stored (typically in pre-decoded form) on the chip by programming a non-volatile element on the chip. Then, during normal operation of the semiconductor memory, if the memory's addressing circuitry receives a memory address including a column address that corresponds to the column address stored on the chip, redundant circuitry in the memory causes a redundant memory cell in the redundant column to be accessed instead of the memory cell identified by the received memory address. Since every memory cell in the failing cell's column has the same column address, every cell in the failing cell's column, both operative and failing, is replaced by a redundant memory cell in the redundant column.

The process described above for repairing a semiconductor memory using redundant rows and columns is well known in the art, and is described in various forms in U.S. Pat. Nos. 4,459,685, 4,598,388, 4,601,019, 5,031,151, 5,257,229, 5,268,866, 5,270,976, 5,287,310, 5,355,340, 5,396,124, 5,422,850, 5,471,426, 5,502,674, 5,511,028, 5,544,106, 5,572,470, 5,572,471, and 5,583,463, the collective contents of which are incorporated herein by reference.

A typical semiconductor memory most often comprises multiple sub-arrays of memory cells. Turning to FIG. 1, an example of a conventional memory array 150 is depicted. For purposes of this description, it will be assumed that each sub-array (100-114) contains 256 rows corresponding to an entire row space of 512 rows. In addition, it will be assumed that a pair of adjacent sub-arrays (e.g., 100, 104) respectively contain rows 0-255 and 256-511. Furthermore, each of the sub-arrays (100-114) can be distinguished by whether they belong to Bank 0 or Bank 1 and whether they belong to an “Even” pairing or an “Odd” pairing. For example, during operation, when a memory cell address is received by the memory array 150 for either a read or a write operation, the same row in two separate sub-arrays 100, 108 is fired in one of Banks 0 or 1. Furthermore, the even/odd pairing designation is known by the most significant bit (MSB), A8, of the row address (A0-A8).

Still referring to FIG. 1, for example, when the address for row 250 is received by the memory array 150, row 250 of two sub-arrays (100, 108) is fired. The bank address (e.g., BnK0, BnK1) enables the proper side of row decoders 128, 142 and 132, 138 to fire the appropriate sub-arrays 100, 108. In this configuration, two sub-arrays 100, 108 of the same bank (e.g., Bnk0) are fired at the same time.

Turning to FIG. 2, the redundancy architecture of the FIG. 1 memory array 150 is described. Each of the sub-arrays 100-114 and their respective couplings are identical to those described in connection with FIG. 1. FIG. 2 illustrates four redundant rows (RR0-RR3) contained in each sub-array (100-114).

During integrity testing of the memory array 150, when a defective cell is detected in a sub-array (e.g., a defective cell located in row 63 of sub-array 106), the entire row containing the defective cell must be replaced with a redundant row (e.g., RR3) located in the same sub-array 106. As a result, all instances of RR3 in Bank 1 is allocated and unavailable for further use. Similarly, if another defective cell is detected (e.g., in row 47 of sub-array 114), the entire row 47 must be replaced with a redundant row (e.g., RR1) in the same sub-array 114. RR1 is then unavailable for further use in Bank 1. If, for example, two more defective cells are detected in sub-array 110 (e.g., cells respectively associated with rows 89 and 25), rows 89 and 25 must be replaced with redundant rows (e.g., RR0 and RR2) located in the same sub-array as the defective cells. RR0 and RR2 are then unavailable for further use in Bank 1. As can be seen, with just four redundant rows available per bank, there is not much flexibility available to the designer.

As mentioned earlier, and as known in the art, once a redundant row (e.g., RR3) of a particular sub-array (e.g., 106) has been assigned to replace a row (e.g., row 63) associated with a defective memory cell, every instance of that redundant row RR3 is now unavailable in all sub-arrays of Bank 1 (102, 106, 110 and 114).

The configurations of FIGS. 1 and 2 are limited in that only four redundant rows are available per bank. It is, thus, desirable to have an architecture which facilitates the sharing of redundant rows between adjacent banks and which gives more repair flexibility.

### SUMMARY OF THE INVENTION

The present invention provides a method and corresponding architecture for sharing redundant rows between banks of a memory array. The architecture is such that sub-arrays associated with different banks are alternated and coupled via a sense amp. In addition, sub-arrays belonging to the same bank are coupled via a single row decoder. This architecture allows for adjacent sub-arrays belonging to different banks to share redundant rows, thereby effectively doubling the number of redundant rows available for use in a given bank.

### BRIEF DESCRIPTION OF THE DRAWINGS

The foregoing and other advantages and features of the invention will become more apparent from the detailed description of preferred embodiments of the invention given below with reference to the accompanying drawings in which:

FIG. 1 depicts a portion of a conventional memory array;

FIG. 2 depicts a conventional redundancy architecture used within the FIG. 1 memory array;

FIG. 3 depicts a portion of a memory array, in accordance with an exemplary embodiment of the invention;

FIG. 4(a) depicts a redundancy architecture used with the FIG. 3 memory array, in accordance with an exemplary embodiment of the invention;

FIG. 4(b) depicts a block diagram of a portion of a memory circuit in accordance with an exemplary embodiment of the invention;

FIG. 5 shows a flowchart depicting an operational flow of the FIG. 4(a) redundancy architecture;

FIG. 6 depicts the FIG. 3 memory array on a semiconductor chip, in accordance with an exemplary embodiment of the invention; and

FIG. 7 depicts a processor system employing the FIG. 3 memory array.

### DETAILED DESCRIPTION OF PREFERRED EMBODIMENTS

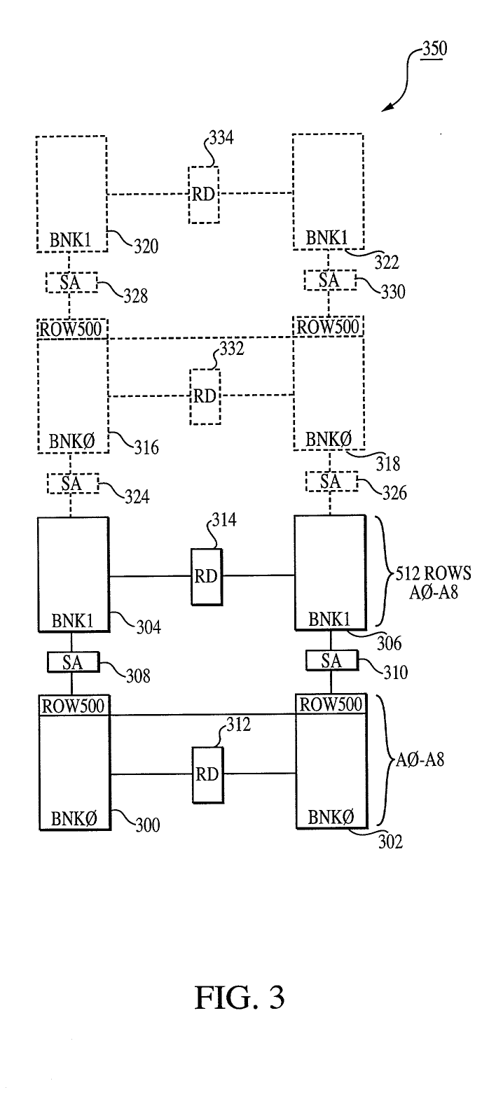

The present invention will be described as set forth in exemplary embodiments described below in connection with FIGS. 3-7. Other embodiments may be realized and other changes may be made to the disclosed embodiments without departing from the spirit or scope of the present invention.

Referring now to FIG. 3, a memory array 350 is depicted in accordance with an exemplary embodiment of the invention. Sub-array 300 of Bank 0 is coupled to sub-array 302 of Bank 0 via a row decoder 312. Sub-array 304 of Bank 1 is coupled to sub-array 306 of Bank 1 via row decoder 314. Additionally, sub-array 300 of Bank 0 is coupled to sub-array 304 of Bank 1 via sense amp 308 and sub-array 302 of Bank 0 is coupled to sub-array 306 of Bank 1 via sense amp 310.

In accordance with an exemplary embodiment of the invention, both sub-arrays 300, 302 of Bank 0 (and both sub-arrays 304, 306 of Bank 1) are aligned such that when a memory address is received by the memory array 350, the same row of both sub-arrays 300 and 302 are fired. For example, if a memory cell located in row 500 is desired for a read or write operation, since both sub-arrays 300, 302 share a row decoder 312, row 500 of both sub-arrays 300, 302 is fired. The exact memory cell desired is then identified by the column decoders (not shown).

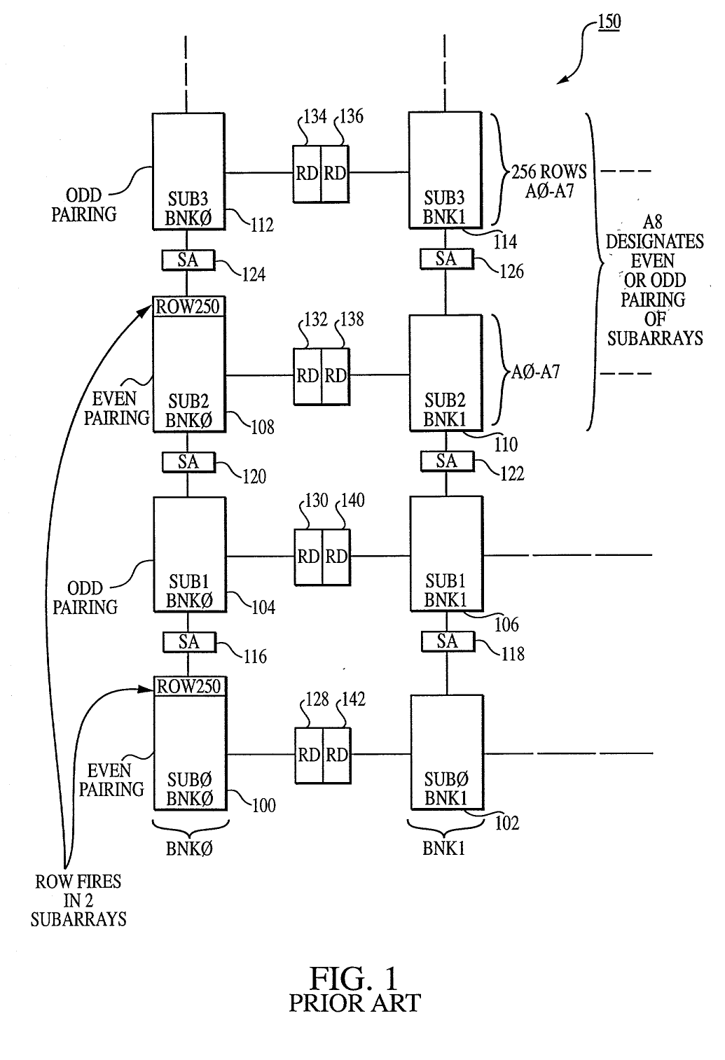

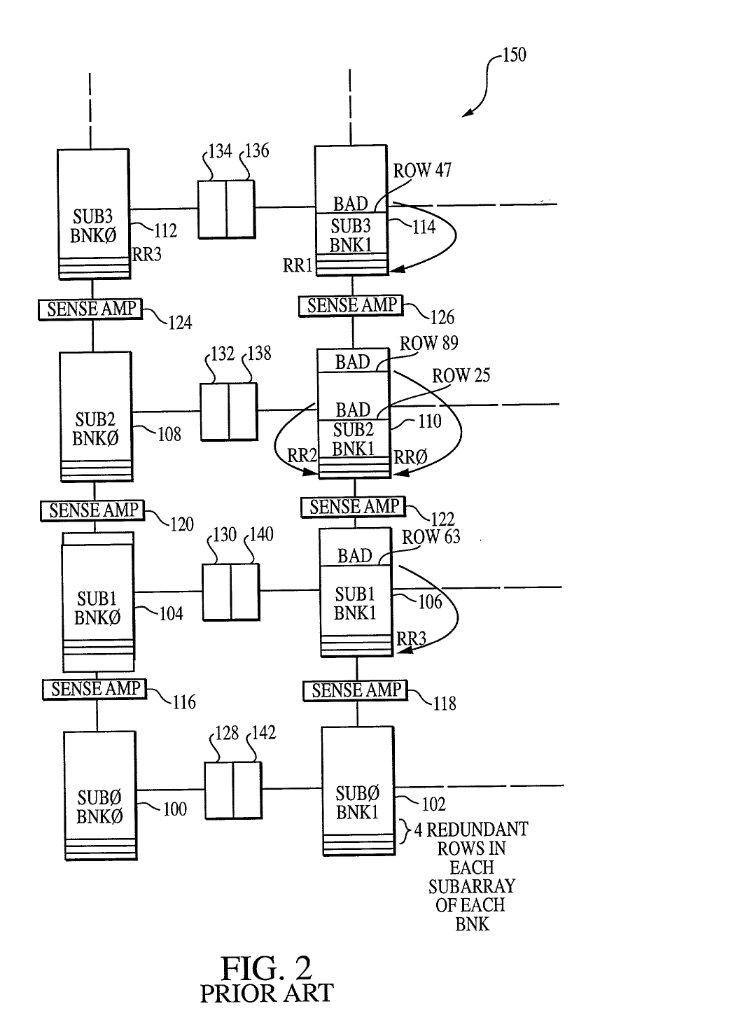

As a result of the FIG. 3 memory array 350, since sub-arrays that share sense amps (e.g., 308) are sub-arrays from different banks, the size of a sub-array can be increased to the size of the entire row space (e.g., 512 rows rather than 256 rows in FIGS. 1 and 2), thereby reducing the number of sense amps required for the same memory capacity and, hence, reducing the die size.

While the same memory capacity as the FIG. 1 array is achieved with the four expanded sub-arrays 300-306 of FIG. 3, it should be readily apparent that the memory array 350 may be expanded to contain additional sub-arrays (e.g., 316-322), additional sense amps (e.g., 324-330) and additional row decoders (e.g., 332, 334), as depicted by the dotted lines.

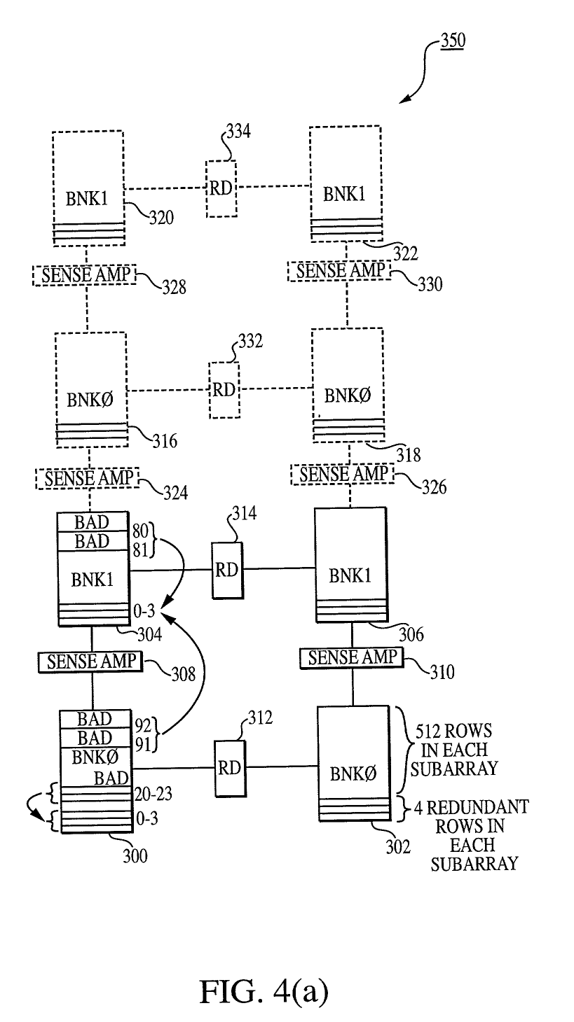

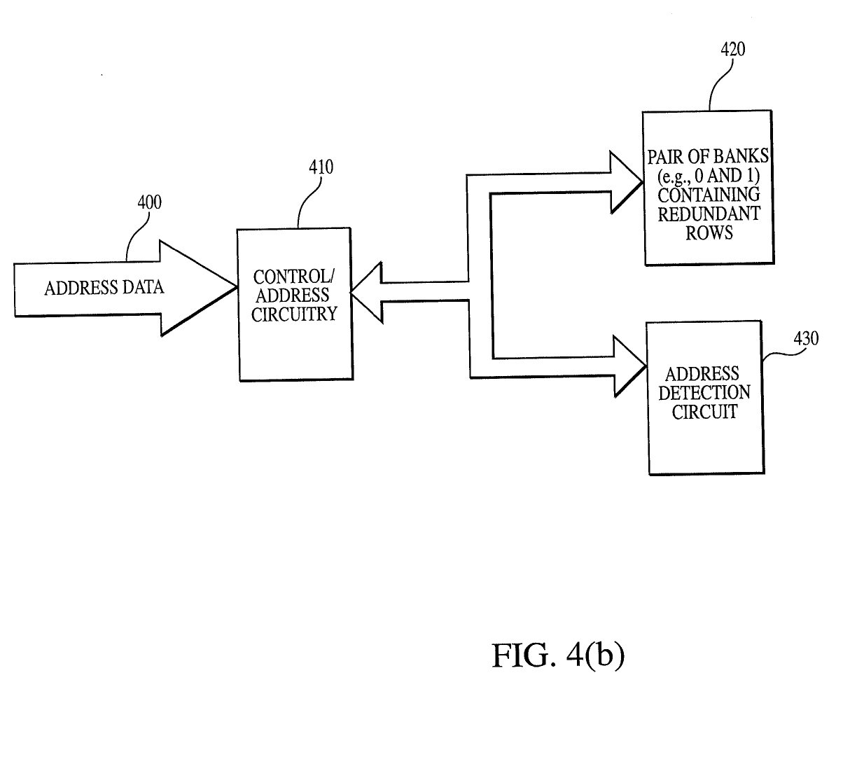

Turning to FIG. 4(a), a redundancy architecture of memory array 350 is depicted in accordance with an exemplary embodiment of the invention. Each of the sub-arrays 300-322 and their respective couplings are identical to those described in connection with FIG. 3 and shall not be repeated here. FIG. 4(a) also illustrates the four redundant rows (RR0-RR3) contained in each sub-array (300-322).

During integrity testing of the memory array 350, when a defective cell, or cells are detected in a sub-array (e.g., four cells respectively located in rows 2023 of sub-array 300), the four rows (20-23) containing the defective cells must be replaced with four redundant rows (e.g., RR0-RR3). In accordance with an exemplary embodiment of the invention, since the sense amp 308 couples sub-arrays 300, 304 of different banks (0 and 1), redundant rows of both banks may be used to effectuate a repair in either one, or both, of the adjacent sub-arrays for a total of eight available redundant rows for the pair of banks (0, 1). That is, either the sub-array pairing of 300 and 304 and/or the pairing of 302 and 306 (and if greater memory capacity is desired, the pairing of 304 and 316 and/or 316 and 320 and/or the pairing of 306 and 318 and/or 318 and 322) can be combined for a total of eight available redundant rows (i.e., two sets of RR0-RR3) for each pair of banks (e.g., 0, 1). In this example, the defective rows 20-23 have been replaced with redundant rows RR0-RR3 of the same sub-array 300. Therefore, all four of the redundant rows available for Bank 0 have been allocated.

Still referring to FIG. 4(a), an additional two defective cells are identified at rows 92 and 91 of the same sub-array 300 of Bank 0. Since no additional redundant rows are available in sub-array 300, in accordance with an exemplary embodiment of the invention, two redundant rows RR0, RR1 of adjacent sub-array 304 belonging to Bank 1 are assigned to replace defective rows 92 and 91. In addition, rows 80 and 81 of sub-array 304 are detected as defective rows. Since there are still two redundant rows (RR2, RR3) available in Bank 1, they are assigned as replacements for defective rows 80 and 81. In this configuration, eight redundant rows may be shared between each pair of adjacent banks. Additionally, it should be noted that, although FIGS. 3 and 4(a) are described as having two banks, the invention may be used with memory arrays that have any number of banks, for example, a memory with 32 banks.

In the above-described example, and also, e.g., in the case of a 32 bank memory array, each pair of banks (e.g., 0 and 1, 2 and 3, 4 and 5, etc.) is associated with an address detection circuit containing a bank of repair elements (e.g., anti-fuses). Turning to FIG. 4(b), for example, the address data enters the memory via address bus 400 and the address is decoded by control/address circuit 410. The decoded address is then forwarded to address detection circuit 430 and the pair of banks 420. The address detection circuit 430 monitors row (and column) addresses and enables a redundant row (or column) if the address of a defective row (or column) is detected. The address detection circuit 430 compares the incoming address with a plurality of defective row addresses encoded in a bank of repair elements (e.g., anti fuses).

The repair elements are programmed so as to signify which row address from which sub-array has been replaced with a redundant row and in which bank the redundant row is located. In addition to containing the row address, and in accordance with an exemplary embodiment of the invention, the bank of repair elements contains a least significant bit (LSB) identifying which bank (e.g., 0 or 1) of the pair of banks served by the address detection circuit 430 contains the defective memory cell. This ensures that when a memory access is desired of, e.g., row 91 of sub-array 304 (i.e., Bank 1), row 91 of sub-array 304 is actually accessed instead of defective row 91 of sub-array 300 (i.e., Bank 0) which was replaced with a redundant row (e.g., RR0) and which does not contain the desired memory cell. Based upon this same principle, the sense amps are also instructed by the information stored in this least significant bit of the repair elements to identify which bank (i.e., which one of the two sub-arrays it couples) should be read.

The address detection circuit 430 is programmed during the manufacturing stage such that if a defective row is detected in a sub array of either one banks 0 or 1, the information as to both the row number and the bank number is forwarded to the address detection circuit 430. Assuming the combined number of redundant rows available to each bank, through the method of sharing redundant rows as described herein, is 8, then there are at least 8 redundant addresses programmable within the address detection circuit 430. Four of the 8 redundant addresses are associated with bank 0 and the other four redundant addresses are associated with bank 1. It is the LSB (and whether or not its corresponding repair element is programmed) that distinguishes whether the redundant row is associated with bank 0 or bank 1.

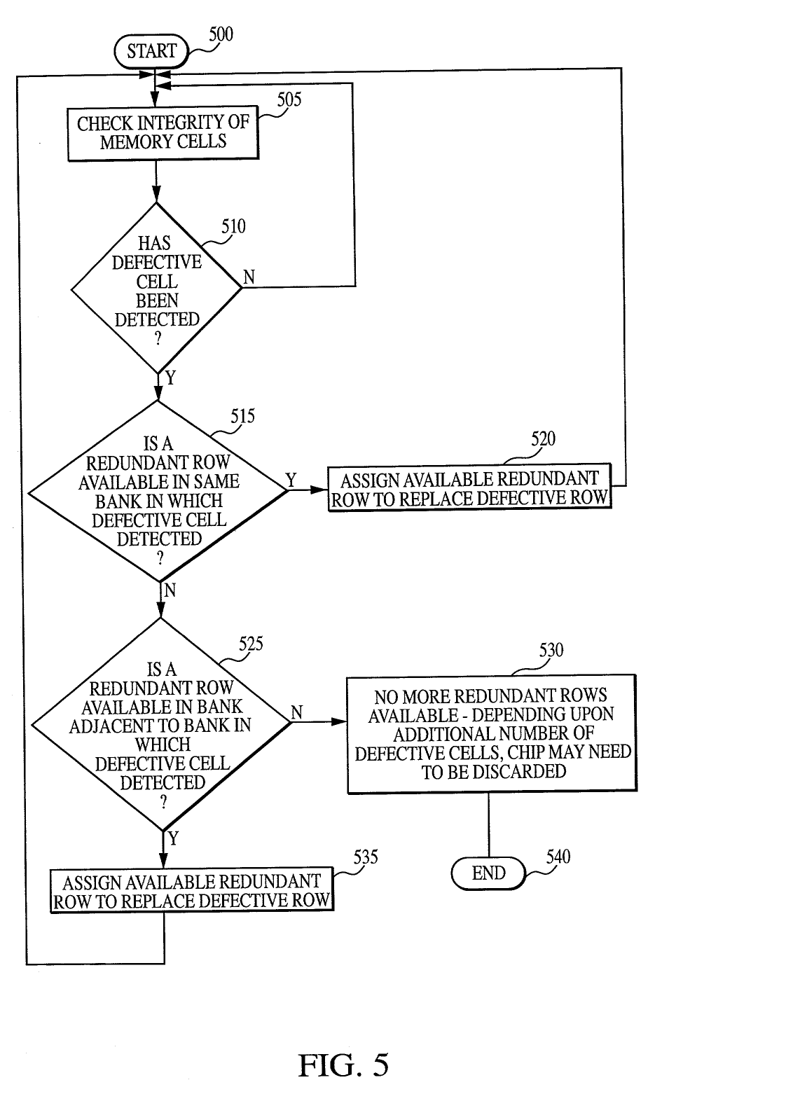

Referring now to FIG. 5, a flowchart describing the operational flow of a method is depicted, in accordance with an exemplary embodiment of the invention. The process begins at segment 500 and at segment 505, an integrity check is performed on memory array 350. At segment 510, a determination is made as to whether any defective cells have been detected. If not, the process flows back to segment 505. If at least one defective cell has been detected, then a determination is made as to whether a redundant row is available in the bank in which the defective cells are detected at process segment 515. If there is at least one redundant row available, then at process segment 520, the available row is assigned to replace the defective row.

If at segment 515, no redundant rows are available in the bank in which the defective row is detected, a determination is made, at segment 525, as to whether a redundant row is available in the adjacent bank (i.e., the bank coupled to the bank, via the sense amp, in which the defective row was detected). If not, no more redundant rows are available in the pair of banks (0 and 1) and depending upon the additional number of defective rows, the chip may need to be discarded at segment 530 and the process ends at segment 540. If a redundant row is available at segment 525, then the redundant row is assigned to replace the defective row at segment 535. The process then returns to segment 505.

In another embodiment, all defective memory cells are detected at once and then a determination is made as to the most efficient way to repair them with respect to adjacent sub-arrays of different banks.

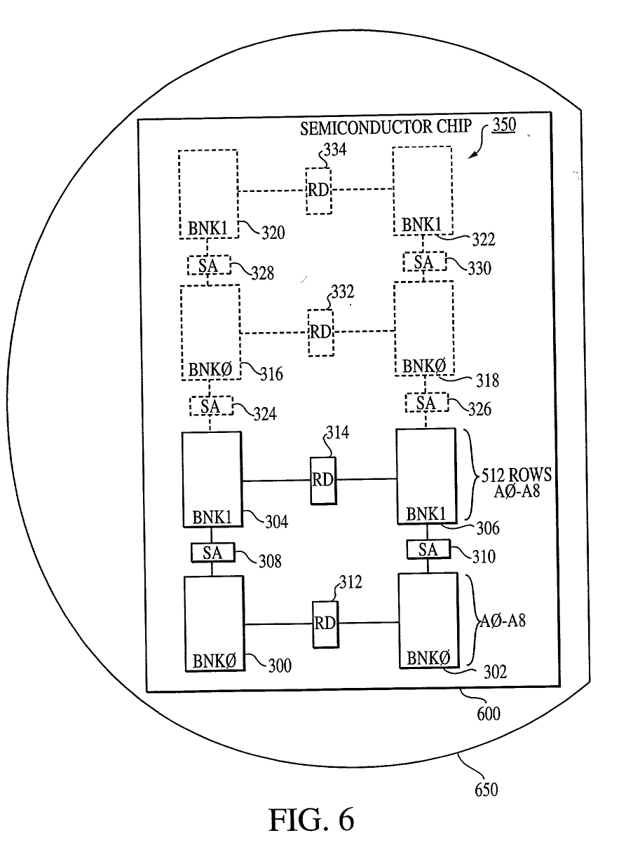

Turning to FIG. 6, a semiconductor chip 600 is depicted on a semiconductor wafer 650 in accordance with an exemplary embodiment of the invention. Pictured on chip 600 is memory array 350 as described in connection with FIG. 3. While the memory array 350 is depicted as having four (and possibly as many as eight) sub-arrays 300-322, it should be readily apparent that semiconductor chip 600 may contain a memory array 350 having any number of sub-arrays. In addition, semiconductor chip 600 likely contains other components which interact with memory array 350 such as address lines, clock lines, fuse banks, etc., which have been omitted for purposes of simplicity. Furthermore, while only one chip 600 is depicted on wafer 650, a plurality of chips similar to chip 600 may be located on wafer 650, and the size of chip 600 relative to wafer 650 has been exaggerated for purposes of describing this exemplary embodiment.

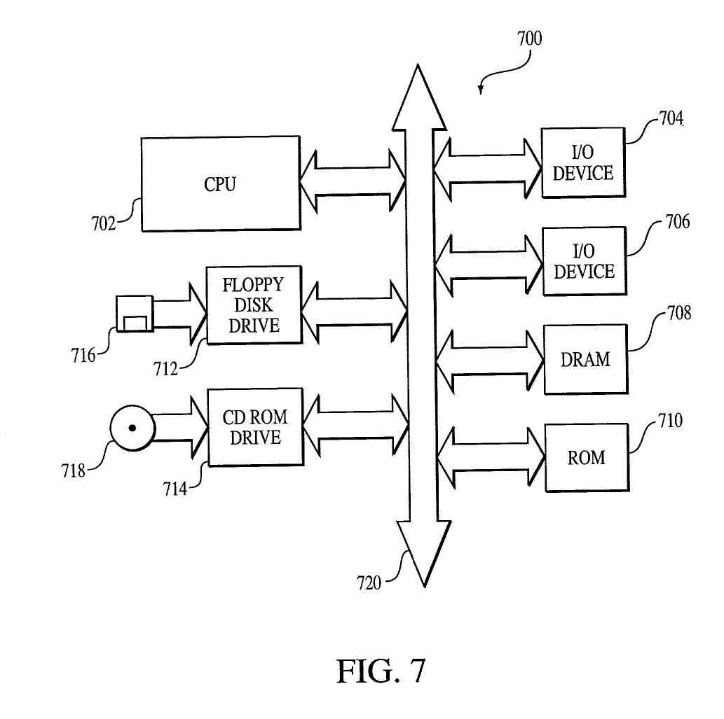

FIG. 7 illustrates a block diagram of a processor system 700 containing a semiconductor memory having a memory array as described in connection with FIGS. 3-6. For example, the memory array 350 described in connection with FIGS. 3-6 may be part of dynamic random access memory (DRAM) 708. The processor-based system 700 may be a computer system or any other processor system. The system 700 includes a central processing unit (CPU) 702, e.g., a microprocessor, that communicates with floppy disk drive 712 and CD ROM drive 714 over a bus 720. It must be noted that the bus 720 may be a series of buses and bridges commonly used in a processor-based system, but for convenience purposes only, the bus 720 has been illustrated as a single bus. An input/output (I/O) device (e.g., monitor) 704, 706 may also be connected to the bus 720, but are not required in order to practice the invention. The processor-based system 700 also includes a read-only memory (ROM) 710 which may also be used to store a software program.

Although the FIG. 7 block diagram depicts only one CPU 702, the FIG. 7 system could also be configured as a parallel processor machine for performing parallel processing. As known in the art, parallel processor machines can be classified as single instruction/multiple data (SIMD), meaning all processors execute the same instructions at the same time, or multiple instruction/multiple data (MIMD), meaning each processor executes different instructions.

The present invention provides a memory array architecture 350 and corresponding method for sharing redundant rows between adjacent memory banks (e.g., 0, 1). The memory array 350 is designed such that adjacent sub-arrays (e.g., 300, 304) of different banks are coupled via a sense amp (e.g., 308) and such that adjacent sub-arrays (e.g., 300, 302) of common banks share a common row decoder (e.g., 312). In accordance with an exemplary embodiment of the invention, adjacent sub-arrays sharing a common sense amp can share redundant rows between them, thus, effectively doubling the number of redundant rows available per pair of banks (e.g., 0, 1). In addition, since sub-arrays that share sense amps are sub-arrays of different banks, the size of a sub-array can be increased to the size of the entire row space, thereby reducing the number of sense amps and, hence, reducing the die size. As a result, fewer sub-arrays, fewer sense amps and fewer row decoders are required for the same memory capacity as compared with conventional memory arrays (e.g., FIG. 1).

While the invention has been described in detail in connection with preferred embodiments known at the time, it should be readily understood that the invention is not limited to the disclosed embodiments. Rather, the invention can be modified to incorporate any number of variations, alterations, substitutions or equivalent arrangements not heretofore described, but which are commensurate with the spirit and scope of the invention. For example, although the invention has been described in connection with a memory array having two banks and up to eight sub-arrays, the invention may be carried out with any number of banks and any number of sub-arrays. In addition, each of the sub-arrays may contain any number of rows. Furthermore, although the invention depicts four redundant rows per sub-array, it should be readily understood that the invention may be practiced with sub-arrays containing fewer or more redundant rows. In addition, although at FIG. 5 a check is made to determine whether a redundant row is available in the same bank in which the defective row is detected, this is not a required action. That is, no check needs to be made within the sub-array containing the defective row before a redundant row in an adjacent bank is used for repair. Accordingly, the invention is not limited by the foregoing description or drawings, but is only limited by the scope of the appended claims.

What is claimed as new and desired to be protected by Letters Patent of the United States is:

1. A method for repairing a defective memory cell, the method comprising:
detecting a defective memory cell in a first bank of a memory array; and
replacing a row in which said defective cell is located with a redundant row in a second bank of said memory array.

2. The method of claim 1, wherein said act of detecting comprises:
detecting said defective memory cell in a first sub-array of said memory array, said first sub-array being associated with a first bank of said memory array.

3. The method of claim 2, wherein said act of replacing comprises replacing said row in which said defective cell is located with a redundant row in a second sub-array of said memory array, said second sub-array being associated with a second bank of said memory array.

4. The method of claim 2, wherein said act of replacing comprises replacing said row in which said defective cell is located with a redundant row in an adjacent sub-array, said adjacent sub-array being coupled to said first sub-array via a sense amp, and said adjacent sub-array being associated with a second bank of said memory array.

5. The method of claim 1 further comprising determining that a redundant row is not available in said first bank of said memory array before performing said act of replacing.

6. The method of claim 4 further comprising:
receiving an instruction to read data from said defective memory cell in said first bank of said memory array; and
reading said data from said redundant row in said adjacent sub-array.

7. The method of claim 4 further comprising:
receiving an instruction to write data to said defective memory cell in said first bank of said memory array; and
writing said data to said redundant row in said adjacent sub-array.

8. A method for repairing a defective memory cell, the method comprising:
detecting a defective memory cell in a first sub-array of a first bank of a memory array; and
replacing a row containing said defective memory cell with a redundant row in a second sub-array of a second bank of said memory array.

9. A method for assigning a redundant row in a memory array, the method comprising:
detecting a defective row of said memory array in a first sub-array of a first bank of said memory array;
programming at least one repair element of an address detection circuit coupled to said memory array so as to signify whether said defective row is to be replaced with a redundant row in said first bank or a redundant row in a second bank of said memory array.

10. The method of claim 9, wherein said act of programming comprises programming a least significant bit of a row address associated with said redundant row.

11. A method of forming a semiconductor memory array, the method comprising:
forming a first plurality of rows associated with a first bank of said memory array; and
forming a second plurality of rows associated with a second bank of said memory array such that a defective row detected in either one of said first or second banks may be replaced with a redundant row in either one of said first or second banks.

12. The method of claim 11 further comprising:
forming a first plurality of sub-arrays associated with said first bank; and
forming a second plurality of sub-arrays associated with said second bank.

13. The method of claim 12, further comprising:
forming a sense amp between a first one of said first plurality of sub-arrays and a first one of said second plurality of sub-arrays; and
forming a sense amp between a second one of said first plurality of sub-arrays and a second one of said second plurality of sub-arrays.

14. The method of claim 13 further comprising:
forming a first row decoder between said first one of said first plurality of sub-arrays and said second one of said first plurality of sub-arrays; and
forming a second row decoder between said first one of said second plurality of sub-arrays and said second one of said second plurality of sub-arrays.

15. A semiconductor memory array comprising:
a first sub-array associated with a first bank of said memory array; and
a second sub-array associated with a second bank of said memory array coupled to said first sub-array, said first and second sub-arrays also coupled to an address detection circuit containing a plurality of repair elements, said repair elements being programmable so as to signify whether a defective row detected in either one of said first or second sub-arrays is to be replaced with a redundant row in either said first or second sub-array.

16. The semiconductor memory array of claim 15, wherein said first and second sub-arrays are coupled via a sense amp.

17. The semiconductor memory array of claim 15, wherein said repair elements comprise anti fuses.

18. A semiconductor chip comprising:
a semiconductor memory array, said semiconductor memory array comprising:
a first sub-array associated with a first bank of said memory array; and
a second sub-array associated with a second bank of said memory array coupled to said first sub-array, said first and second sub-arrays also coupled to an address detection circuit containing a plurality of repair elements, said repair elements being programmable so as to signify whether a defective row detected in either one of said first or second sub-arrays is to be replaced with a redundant row in either said first or second sub-array.

19. The semiconductor chip of claim 18, wherein said first and second sub-arrays are coupled via a sense amp.

20. The semiconductor chip of claim 18, wherein said repair elements comprise anti fuses.

21. The semiconductor chip of claim 18, wherein said semiconductor chip is formed on a semiconductor wafer.

22. A processor system comprising:
a processor;
a semiconductor memory array coupled to said processor with a bus, said semiconductor memory array comprising:
a first sub-array associated with a first bank of said memory array; and
a second sub-array associated with a second bank of said memory array coupled to said first sub-array, said first and second sub-arrays also coupled to an address detection circuit containing a plurality of repair elements, said repair elements being programmable so as to signify whether a defective row detected in either one of said first or second sub-arrays is to be replaced with a redundant row in either said first or second sub-array.
